(19) United States
(12) Patent Application Publication
(10) Pub. No.: US 2025/0385221 A1
(43) Pub. Date: Dec. 18, 2025

(54) SEMICONDUCTOR PACKAGE DEVICE HAVING FAN-OUT STRUCTURE AND METHOD OF MANUFACTURING THE SAME

(71) Applicant: SILICON BOX PTE. LTD., Singapore (SG)

(72) Inventors: Byung Joon HAN, Seoul (KR); Young Michael HAN, New York, NY (US); Byung Hoon AHN, Yongin-si Gyeonggi-do (KR)

(73) Assignee: SILICON BOX PTE. LTD., Singapore (SG)

(21) Appl. No.: 19/238,653

(22) Filed: Jun. 16, 2025

(30) Foreign Application Priority Data
Jun. 18, 2024 (KR) 10-2024-0078972
Mar. 19, 2025 (KR) 10-2025-0035043

(51) Int. Cl. H01L 23/00; H01L 21/56; H01L 23/31; H01L 25/04

(52) U.S. Cl. CPC H01L 24/96; H01L 21/561; H01L 21/565; H01L 21/568; H01L 23/3107; H01L 24/13; H01L 24/14; H01L 24/32; H01L 25/04; H01L 2224/13016; H01L 2224/14; H01L 2224/29566; H01L 2224/2957; H01L 2224/96

(57) ABSTRACT

Disclosed is a method of manufacturing a semiconductor package device having a fan-out structure, the method including providing a unit device structure including a semiconductor chip having a plurality of bumps disposed on one surface thereof and a non-conductive cover layer disposed to cover the one surface and at least a part of a side surface of the semiconductor chip so as to fill a space between and around the plurality of bumps, the non-conductive cover layer being configured to expose the plurality of bumps, and manufacturing a semiconductor package device having a fan-out structure using the unit device structure.

### CROSS-REFERENCE TO RELATED APPLICATIONS

This application claims priority to Korean Patent Application No. 10-2024-0078972, filed on Jun. 18, 2024, and Korean Patent Application No. 10-2025-0035043, filed on Mar. 19, 2025, the entire contents of which are herein incorporated by reference.

### BACKGROUND OF THE INVENTION

### 1. Field of the Invention

The present invention relates to semiconductor package-related technology and methods, and more particularly to a semiconductor package device, a method of manufacturing the same, a unit chip structure applied to the semiconductor package device, and a method of manufacturing the same.

### 2. Description of the Related Art

A semiconductor process may be divided into a front-end process of manufacturing a wafer and engraving a circuit and a back-end process of packaging a chip. As semiconductor miniaturization technology approaches its limits, importance of the back-end process is further increasing. In this regard, advanced packaging technology that integrates different semiconductor chips or vertically connects a plurality of chips to each other is emerging as important technology. Recently developed artificial intelligence (AI) and high-performance computing (HPC) products may be constituted by a system-on-chip (SOC) such as a high bandwidth memory (HBM), a central processing unit (CPU), a neural processing unit (NPU), and a graphics processing unit (GPU).

2.5-dimensional (2.5D) packaging is packaging technology that integrates a plurality of semiconductor chips (dies) into a single package after horizontally disposing the plurality of semiconductor chips. 2.5D packaging is different from 3D packaging in that each chip is disposed on an interposer, which is a packaging part. A logic chip and a memory chip may be horizontally disposed on the interposer.

Embedded multi-die interconnect bridge (EMIB) technology uses a silicon interposer in order to connect heterogeneous semiconductor chips (dies) to each other, wherein the silicon interposer is embedded in a flip chip ball grid array (FC-BGA) substrate, which is referred to as a silicon bridge. EMIB technology has advantages such as board area reduction, package height reduction, and power consumption reduction, and is capable of reducing production cost since the area of the silicon bridge is less than that of a general silicon interposer.

Chip-on-wafer-on-substrate (CoWoS), a type of 2.5D packaging technology, means that two or more semiconductor chips are interconnected on a wafer and then disposed on a package substrate. The memory chip and the logic chip may be horizontally mounted on the interposer or may be vertically stacked on the interposer. In order to implement CoWoS, interposer technology that connects a plurality of chips like a single die is primarily used. The interposer is a type of substrate, but is characterized by only routing signals without any logic functions.

However, common characteristics of advanced packages, such as EMIB and CoWoS, are that chips (dies) cannot be connected to each other without a medium such as an interposer. This results in limitations on routing density, which leads to fine lines/spaces. In addition, in most cases, the interposer is used for interconnection of heterogeneous chips at a wafer level, and these processes have the disadvantages of poor productivity, inefficiency, and relatively high production cost.

Fan-out packaging technology, particularly chip-first fan-out packaging, may be a solution to overcome the limitations and problems of existing packages that use interposers. However, when a high bandwidth memory (HBM) or other products are provided in a chip or package form having bumps, it may be difficult to utilize the advantages of chip-first fan-out packaging. That is, a chip/package or product having bumps is suitable for a chip-last process, in which the chip is attached in the latter half of the process, making it difficult to utilize the advantages of the chip-first process.

### SUMMARY OF THE INVENTION

It is an object of the present invention to provide technology and methods capable of applying a chip/package or product having bumps to fan-out packaging.

It is another object of the present invention to provide a method of manufacturing a semiconductor package device by applying a chips or package (package chip) having bumps, for example, to chip-first fan-out packaging and a semiconductor package device manufactured thereby.

The objects of the present invention are not limited to the above objects, and other unmentioned objects will be understood by those skilled in the art based on the following description.

In accordance with aspect of the present invention, the above and other objects can be accomplished by the provision of a method of manufacturing a semiconductor package device having a fan-out structure, the method including providing a unit device structure including a semiconductor chip having a plurality of bumps disposed on one surface thereof and a non-conductive cover layer disposed to cover the one surface and at least a part of a side surface of the semiconductor chip so as to fill the space between and around the plurality of bumps, the non-conductive cover layer being configured to expose the plurality of bumps, and manufacturing a semiconductor package device having a fan-out structure using the unit device structure, the semiconductor package device including the unit device structure, a molding layer configured to form a single substrate layer together with the unit device structure while filling the space around the unit device structure, the molding layer being configured to expose one surface of the unit device structure such that the plurality of bumps is exposed, a redistribution layer member disposed on one surface of the substrate layer including the unit device structure and the molding layer so as to be electrically connected to the plurality of bumps, and a plurality of electrical connection elements disposed on one surface of the redistribution layer member so as to be electrically connected to the semiconductor chip via the redistribution layer member on the side opposite the side on which the substrate layer is disposed.

The step of providing the unit device structure may include providing a molding tool including a molding unit having an accommodation region, filling at least a part of the accommodation region with a non-conductive material, disposing the semiconductor chip having a plurality of bump elements in the accommodation region filled with the non-conductive material in the at least a part thereof, separating a combined body in which the semiconductor chip and the non-conductive material are combined with each other from the molding unit, and polishing one surface of the combined body to two-dimensionally expose the plurality of bump elements, wherein, after the polishing, the combined body may correspond to the unit device structure, the plurality of bump elements may correspond to the plurality of bumps, and the non-conductive material may correspond to the non-conductive cover layer.

The non-conductive material in the combined body may be disposed so as to cover a part or the entirety of the side surface of the semiconductor chip.

The step of providing the unit device structure may include providing a temporary substrate, disposing the semiconductor chip having the plurality of bump elements on the temporary substrate, the semiconductor chip being provided in plural, forming a non-conductive material layer configured to mold the plurality of semiconductor chips on the temporary substrate, polishing one surface of a combined structure in which the plurality of semiconductor chips and the non-conductive material layer are combined with each other to two-dimensionally expose the plurality of bump elements, and dividing the combined structure into device units to form the unit device structure in plural in the state in which the temporary substrate is excluded, wherein, after the polishing or the dividing, the plurality of bump elements may correspond to the plurality of bumps, and the non-conductive material layer may correspond to the non-conductive cover layer.

In the step of disposing the plurality of semiconductor chips on the temporary substrate, each semiconductor chip may be disposed in a first direction such that the plurality of bump elements is located between the temporary substrate and the semiconductor chip, or each semiconductor chip may be disposed in a second direction opposite the first direction such that the semiconductor chip is located between the temporary substrate and the plurality of bump elements.

The non-conductive cover layer may include a first part disposed on the one surface of the semiconductor chip and a second part extending from the first part so as to cover a part or the entirety of the side surface of the semiconductor chip.

Each of the plurality of bumps may have a polished surface, and the polished surface may be disposed in the same plane as one surface of the non-conductive cover layer and exposed to the outside of the non-conductive cover layer.

The semiconductor package device may include a plurality of unit device structures, at least one of which corresponds to the unit device structure, the plurality of unit device structures being disposed spaced apart from each other in a horizontal direction, and the molding layer may be disposed so as to fill the space between and around the plurality of unit device structures.

At least two of the plurality of unit device structures may include different types of semiconductor chips.

The step of manufacturing the semiconductor package device may include disposing the plurality of unit device structures on a carrier substrate so as to be spaced apart from each other in the horizontal direction, at least one of the plurality of unit device structures being disposed in each of a plurality of two-dimensionally arranged unit package regions, forming a molding material layer configured to cover the plurality of unit device structures on the carrier substrate, removing the carrier substrate from a substrate structure including the molding material layer and the plurality of unit device structures, forming a redistribution layer structure electrically connected to the plurality of bumps on one surface of the substrate structure, forming the plurality of electrical connection elements on one surface of the redistribution layer structure in each of the plurality of unit package regions, and dividing a packaging structure including the plurality of unit device structures, the molding material layer, the redistribution layer structure, and the plurality of electrical connection elements into package device units corresponding to the plurality of unit package regions, respectively.

The semiconductor package device may have a single-chip package structure or a multi-chip package structure.

In accordance with another aspect of the present invention, there is provided a semiconductor package device having a fan-out structure, the semiconductor package device including a unit device structure including a semiconductor chip having a plurality of bumps disposed on one surface thereof and a non-conductive cover layer disposed to cover the one surface and at least a part of a side surface of the semiconductor chip so as to fill the space between and around the plurality of bumps, the non-conductive cover layer being configured to expose the plurality of bumps, a molding layer configured to form a single substrate layer together with the unit device structure while filling the space around the unit device structure, the molding layer being configured to expose one surface of the unit device structure such that the plurality of bumps is exposed, a redistribution layer member disposed on one surface of the substrate layer including the unit device structure and the molding layer so as to be electrically connected to the plurality of bumps, and a plurality of electrical connection elements disposed on one surface of the redistribution layer member so as to be electrically connected to the semiconductor chip via the redistribution layer member on the side opposite the side on which the substrate layer is disposed.

The non-conductive cover layer may include a first part disposed on the one surface of the semiconductor chip and a second part extending from the first part so as to cover a part or the entirety of the side surface of the semiconductor chip.

Each of the plurality of bumps may have a polished surface, and the polished surface may be disposed in the same plane as one surface of the non-conductive cover layer and exposed to the outside of the non-conductive cover layer.

A plurality of unit device structures, at least one of which corresponds to the unit device structure, may be disposed spaced apart from each other in the horizontal direction, and the molding layer may be disposed so as to fill the space between and around the plurality of unit device structures.

At least two of the plurality of unit device structures may include different types of semiconductor chips.

The semiconductor package device may have a single-chip package structure or a multi-chip package structure.

### BRIEF DESCRIPTION OF THE DRAWINGS

FIGS. 1A, 1B, 1C, 1D, 1E, and 1F are sectional views illustratively showing a method of manufacturing a unit device structure that is applicable to a method of manufacturing a semiconductor package device having a fan-out structure, as an embodiment of the present invention;

FIGS. 2A and 2B are sectional views illustratively showing a method of manufacturing a unit device structure that is applicable to a method of manufacturing a semiconductor package device having a fan-out structure, as another embodiment of the present invention;

FIGS. 3A, 3B, 3C, 3D, 3E, and 3F are sectional views illustratively showing a method of manufacturing a unit device structure that is applicable to a method of manufacturing a semiconductor package device having a fan-out structure, as another embodiment of the present invention;

FIGS. 4A, 4B, 4C, 4D, and 4E are sectional views illustratively showing a method of manufacturing a unit device structure that is applicable to a method of manufacturing a semiconductor package device having a fan-out structure, as another embodiment of the present invention;

FIGS. 5A, 5B, 5C, 5D, and 5E are sectional views illustratively showing a method of manufacturing a semiconductor package device having a fan-out structure according to an embodiment of the present invention;

FIG. 5E is a sectional view illustratively showing a semiconductor package device having a fan-out structure according to an embodiment of the present invention;

FIGS. 6A, 6B, 6C, 6D, and 6E are sectional views illustratively showing a method of manufacturing a semiconductor package device having a fan-out structure according to another embodiment of the present invention;

FIG. 6E is a sectional view illustratively showing a semiconductor package device having a fan-out structure according to another embodiment of the present invention;

FIG. 7 is a sectional view illustratively showing a semiconductor package device having a fan-out structure according to another embodiment of the present invention; and

FIG. 8 is a sectional view illustratively showing a semiconductor package device having a fan-out structure according to another embodiment of the present invention.

### DETAILED DESCRIPTION

Hereinafter, embodiments of the present invention will be described in detail with reference to the accompanying drawings.

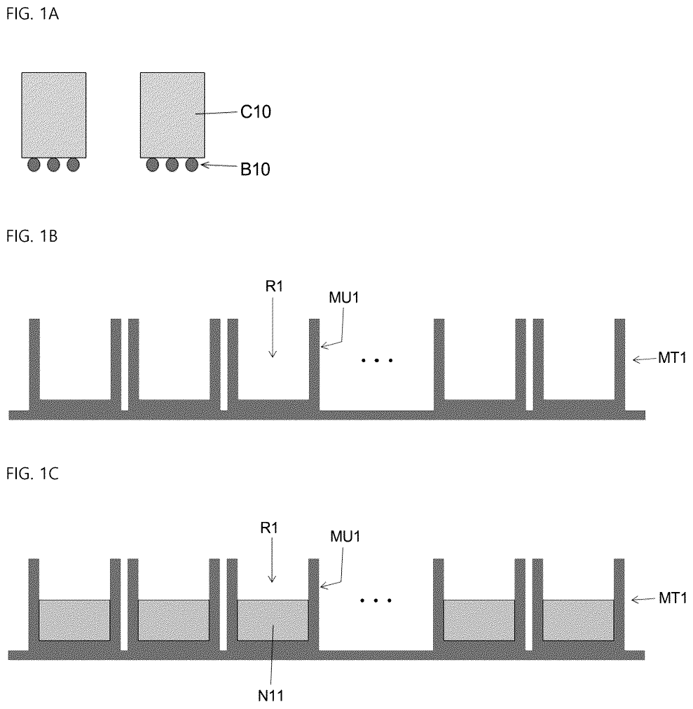

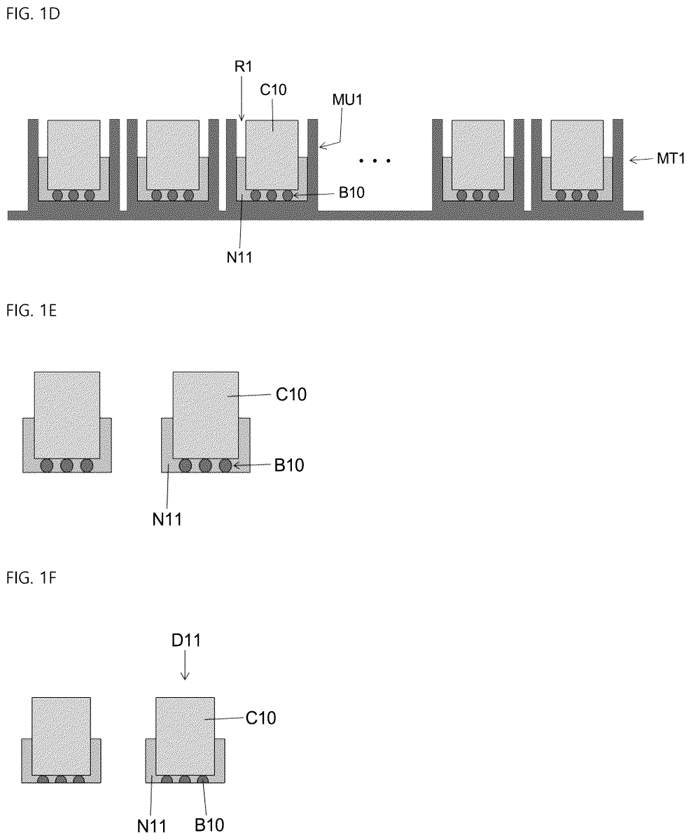

FIGS. 1A, 1B, 1C, 1D, 1E, and 1F are sectional views illustratively showing a method of manufacturing a unit device structure that is applicable to a method of manufacturing a semiconductor package device having a fan-out structure, as an embodiment of the present invention.

Referring to FIG. 1A, a semiconductor chip C10 having a plurality of bumps B10 disposed on one surface thereof may be provided. The semiconductor chip C10 may be a general chip (i.e., a die) or a packaged chip (i.e., a semiconductor package). As a specific example, the semiconductor chip C10 may include a high bandwidth memory (HBM); however, the present invention is not limited thereto. In some cases, the semiconductor chip C10 may include a stack structure in which a plurality of chips (dies) is stacked in a vertical direction.

A plurality of bumps B10 may be provided on one surface of the semiconductor chip C10. The plurality of bumps B10 may be provided for electrical connection and may be referred to as bump elements. The plurality of bumps B10 may be formed on any one of two main surfaces (an upper surface and a lower surface) of the semiconductor chip C10. The plurality of bumps B10 may be disposed on one surface of the semiconductor chip C10 so as to protrude in a direction perpendicular thereto. Each of the plurality of bumps B10 may have a pillar shape or may, at least partially, have a ball shape. In a specific example, each of the bumps B10 may include a metal pillar extending vertically from one surface of the semiconductor chip C10 and a solder cap configured to cover an end of the metal pillar. Here, the metal pillar may be formed so as to include copper (Cu) or other metallic materials. In some cases, each of the bumps B10 may have the configuration of a general solder bump. Additionally, in an example, the plurality of bumps B10 may be microbumps. In this case, each of the plurality of bumps B10 may have a diameter (width) of approximately 100 μm or less, as a non-limiting example.

The semiconductor chip C10 may include a plurality of bonding pads (electrode pads) disposed on one surface thereof, and the plurality of bumps B10 may be disposed on the plurality of bonding pads, respectively. Each of the bonding pads may be made of a metal or a metallic material. Although the semiconductor chip C10 and the bumps B10 are simply shown in FIG. 1A, a large number of bumps B10 may be disposed on one surface of the semiconductor chip C10. The semiconductor chip C10 may be provided in plural.

Referring to FIG. 1B, a molding tool MT1 including a molding unit MU1 having an accommodation region R1 may be provided. The molding tool MT1 may include a plurality of molding units MU1. The plurality of molding units MU1 may be disposed on a predetermined base portion in contact with or adjacent to each other, and the inlet of the accommodation region R1 may be open upward. For example, the molding tool MT1 may be made of a metal. The molding tool MT1 may be a mold for potting.

Referring to FIG. 1C, at least a part of the accommodation region R1 may be filled with a non-conductive material N11. The non-conductive material N11 may be, for example, a molding compound. Here, the molding compound may be in a liquid state or a state close to a liquid. A state close to a liquid may mean a paste (fluid paste) state having predetermined viscosity. In a broad sense, a state close to a liquid may also be regarded as a “liquid state”. The accommodation region R1 may be filled with the non-conductive material N11 to a predetermined height of the accommodation region R1 by adjusting the amount of the non-conductive material N11 to be introduced.

Referring to FIG. 1D, the semiconductor chip C10 having the plurality of bumps B10 may be disposed in the accommodation region R1 filled with the non-conductive material N11 in at least a part thereof. At this time, the semiconductor chip C10 may be introduced into the accommodation region R1 such that the plurality of bumps B10 faces downward. The plurality of bumps B10 may be disposed on a bottom surface of the molding unit MU1 so as to be in contact therewith or adjacent thereto. The plurality of bumps B10 and at least a part of the semiconductor chip C10 may be dipped in the non-conductive material N11. The non-conductive material N11 in a liquid state or a state close to a liquid may surround the plurality of bumps B10 and at least a part of the semiconductor chip C10. This may be described as a kind of potting process.

Subsequently, the non-conductive material N11 may be cured. As a non-limiting example, the non-conductive material N11 may be cured using a thermal curing method. The heating temperature for curing the non-conductive material N11 may be appropriately selected depending on the composition of the non-conductive material N11. However, the curing method is not limited to thermal curing and may vary depending on the case. The semiconductor chip C10 and the non-conductive material N11 may be strongly bonded to each other through the curing process, whereby a combined body may be formed.

Referring to FIG. 1E, the combined body in which the semiconductor chip C10 and the non-conductive material N11 are combined with each other may be separated from the molding unit MU1 (FIG. 1D). That is, the combined body may be separated and removed from the molding unit MU1 (FIG. 1D). In the step of FIG. 1C, a release agent such as a wax material may be applied to an inner surface of the molding unit MU1, and then the non-conductive material N11 may be introduced into the accommodation region R1. In this case, the combined body may be easily separated from the molding unit MU1 (FIG. 1D).

In the combined body, the non-conductive material N11 may be disposed so as to cover one surface (a lower surface in the figure) of the semiconductor chip C10 on which the plurality of bumps B10 is disposed and to cover a part of a side surface of the semiconductor chip C10. The non-conductive material N11 may cover a part of each of four side surfaces of the semiconductor chip C10.

Referring to FIG. 1F, one surface of the combined body may be polished to two-dimensionally expose the plurality of bumps B10. The bumps B10 and a part of the non-conductive material N11 therearound may be polished to two-dimensionally expose each bump B10 using a mechanical method, such as grinding or buffing, or a chemical polishing or chemical-mechanical polishing method. At this time, the polishing thickness of the bump B10 may correspond to approximately 1/10 to 9/10 or approximately ⅕ to ⅘ of the initial thickness (length) of the bump B10.

After polishing, the combined body may be referred to as a unit device structure D11. In addition, after polishing, the non-conductive material N11 may be referred to as a non-conductive cover layer N11. The unit device structure D11 may include a semiconductor chip C10 having a plurality of bumps B10 disposed on one surface thereof and a non-conductive cover layer N11. The non-conductive cover layer N11 may be disposed to cover one surface and at least a part of the side surface of the semiconductor chip C10 so as to fill the space between and around the plurality of bumps B10. In addition, the non-conductive cover layer N11 may be disposed so as to expose the plurality of bumps B10. Each of the plurality of bumps B10 may be two-dimensionally exposed from the non-conductive cover layer N11.

If each of the bumps B10 has a structure including a metal pillar and a solder cap configured to cover an end of the metal pillar, the solder cap may be removed and the metal pillar may be exposed by polishing in the step of FIG. 1F. However, the present invention is not limited thereto. The initial structure of the bump B10 is not limited to the structure including the metal pillar and the solder cap, and may vary depending on the case.

As shown in FIG. 1F, the bump B10 two-dimensionally exposed while surrounded by the non-conductive cover layer N11 may function as a kind of electrode pad. The unit device structure D11 may be referred to as a packaged chip (product), a re-packaged package chip (product), or a re-formed chip/package (product). The unit device structure D11 may be easily applied to a fan-out packaging process, such as a chip-first fan-out packaging process. The unit device structure D11 may also be referred to as a “unit chip structure”.

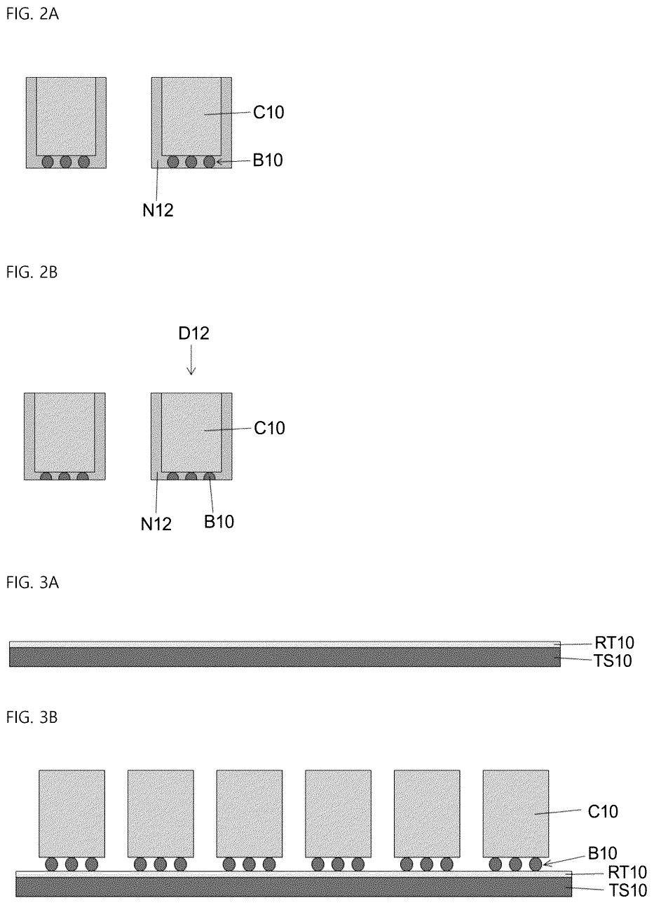

Depending on the height of the non-conductive material N11 surrounding the semiconductor chip C10 in the accommodation region R1 in the step of FIG. 1D, the disposition range of the non-conductive material N11 may change in FIGS. 1E and 1F. The non-conductive material N11 may be disposed so as to cover the entirety of the side surface of the semiconductor chip C10. The example thereof is shown in FIGS. 2A and 2B.

FIGS. 2A and 2B are sectional views illustratively showing a method of manufacturing a unit device structure that is applicable to a method of manufacturing a semiconductor package device having a fan-out structure, as another embodiment of the present invention.

Referring to FIG. 2A, a combined body in which a semiconductor chip C10 and a non-conductive material N12 are combined with each other may be separated from the molding unit MU1 (FIG. 1D). In the combined body, the non-conductive material N12 may be disposed so as to cover the entirety of a side surface of the semiconductor chip C10 while covering one surface (a lower surface in the figure) of the semiconductor chip C10 on which a plurality of bumps B10 is disposed. The non-conductive material N12 may completely cover four side surfaces of the semiconductor chip C10.

Referring to FIG. 2B, one surface of the combined body may be polished to two-dimensionally expose the plurality of bumps B10. After polishing, the combined body may be referred to as a unit device structure D12. In addition, after polishing, the non-conductive material N12 may be referred to as a non-conductive cover layer N12. The unit device structure D12 may include a semiconductor chip C10 having a plurality of bumps B10 disposed on one surface thereof and a non-conductive cover layer N12. The non-conductive cover layer N12 may be disposed so as to cover one surface and the side surface of the semiconductor chip C10 while filling the space between and around the plurality of bumps B10. In addition, the non-conductive cover layer N12 may be disposed so as to expose the plurality of bumps B10. Each of the plurality of bumps B10 may be two-dimensionally exposed from the non-conductive cover layer N12.

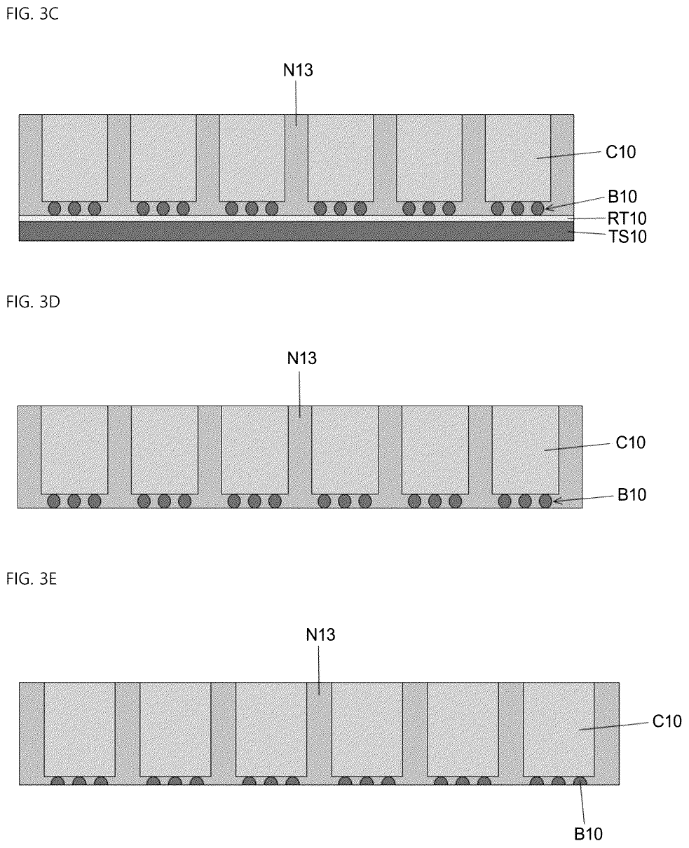

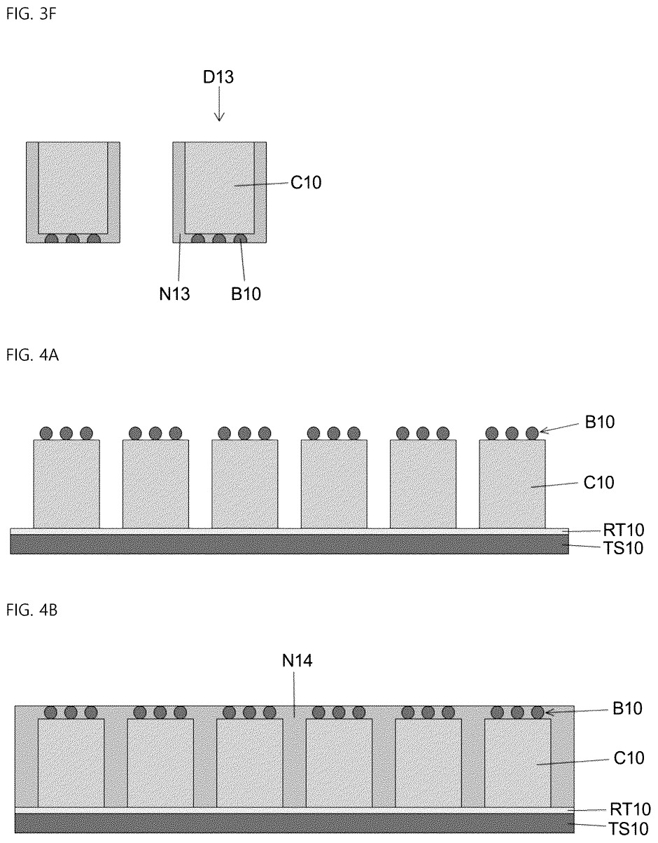

FIGS. 3A, 3B, 3C, 3D, 3E, and 3F are sectional views illustratively showing a method of manufacturing a unit device structure that is applicable to a method of manufacturing a semiconductor package device having a fan-out structure, as another embodiment of the present invention.

Referring to FIG. 3A, a temporary substrate TS10 may be provided. The temporary substrate TS10 may also be referred to as a carrier substrate. As needed, a thermal release tape RT10 may be applied to the temporary substrate TS10. The thermal release tape RT10 may be a tape that loses adhesiveness upon heating above a predetermined temperature. Referring to FIG. 3B, a semiconductor chip C10 having a plurality of bumps B10 as described with reference to FIG. 1A may be disposed on the temporary substrate TS10. For example, the semiconductor chip C10 may be disposed on the temporary substrate TS10 such that the bumps B10 face downward. The semiconductor chip C10 may be disposed in a first direction such that the plurality of bumps B10 is located between the temporary substrate TS10 and the semiconductor chip C10. A plurality of semiconductor chips C10 may be disposed on the temporary substrate TS10. When the thermal release tape RT10 is used, the semiconductor chips C10 may be attached to the thermal release tape RT10.

Referring to FIG. 3C, a non-conductive material layer N13 configured to mold the plurality of semiconductor chips C10 may be formed on the temporary substrate TS10. The non-conductive material layer N13 may include a polymer material. For example, the non-conductive material layer N13 may be a molding compound or may include the same.

Referring to FIG. 3D, the temporary substrate TS10 (FIG. 3C) may be removed from the plurality of semiconductor chips C10 and the non-conductive material layer N13. At this time, the thermal release tape RT10 (FIG. 3C) may be removed together with the temporary substrate TS10 (FIG. 3C). For example, the thermal release tape RT10 may be separated from the non-conductive material layer N13 together with the temporary substrate TS10 by heating the thermal release tape RT10 to above the release temperature.

Referring to FIG. 3E, one surface of a combined structure in which the plurality of semiconductor chips C10 and the non-conductive material layer N13 are combined with each other may be polished to two-dimensionally expose the plurality of bumps B10. Similarly to what has been described with reference to FIG. 1F, the bumps B10 and a part of the non-conductive material N13 therearound may be polished to two-dimensionally expose each bump B10 using a mechanical method, such as grinding or buffing, or a chemical polishing or chemical-mechanical polishing method. At this time, the polishing thickness of the bump B10 may correspond to approximately 1/10 to 9/10 or approximately ⅕ to ⅘ of the initial thickness (length) of the bump B10.

Referring to FIG. 3F, the combined structure may be divided (cut) into device units to form a plurality of unit device structures D13. This may be performed using a general division (cutting) method. Such division may be referred to as a sawing process or a dicing process. As a result, individualized unit device structures D13 may be obtained.

After division, the non-conductive material N13 in the unit device structure D13 may be referred to as a non-conductive cover layer N13. The unit device structure D13 may include a semiconductor chip C10 having a plurality of bumps B10 disposed on one surface thereof and a non-conductive cover layer N13. The non-conductive cover layer N13 may be disposed to cover one surface and at least a part of the side surface of the semiconductor chip C10 so as to fill the space between and around the plurality of bumps B10. The non-conductive cover layer N13 may cover at least a part of each of four side surfaces of the semiconductor chip C10. In addition, the non-conductive cover layer N13 may be disposed so as to expose the plurality of bumps B10. Each of the plurality of bumps B10 may be two-dimensionally exposed from the non-conductive cover layer N13.

The unit device structure D13 may be referred to as a packaged chip (product), a re-packaged package chip (product), or a re-formed chip/package (product). The unit device structure D13 may be easily applied to a fan-out packaging process, such as a chip-first fan-out packaging process.

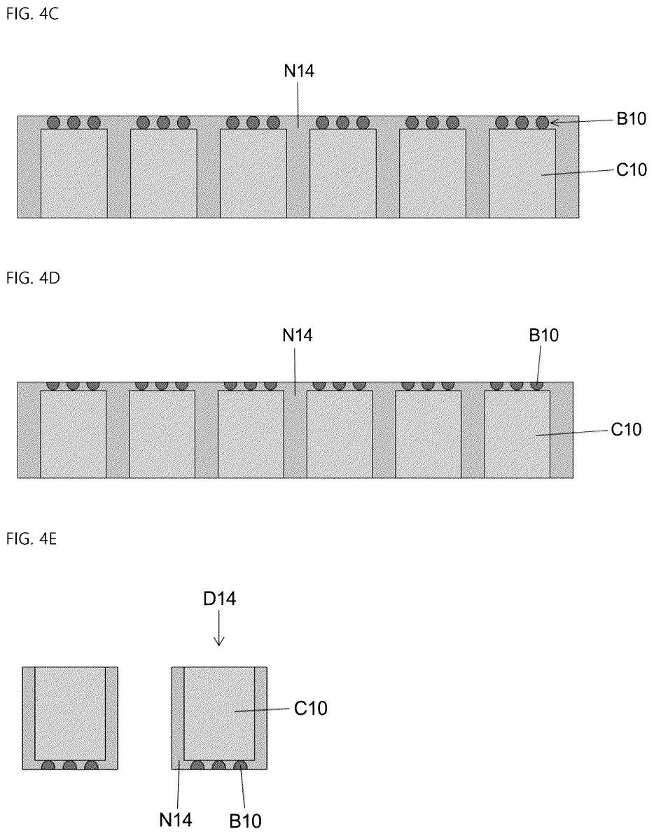

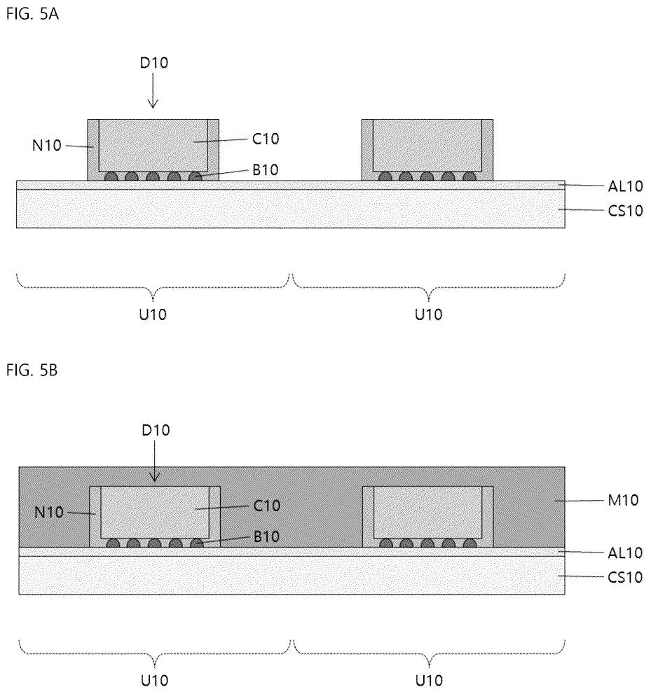

FIGS. 4A, 4B, 4C, 4D, and 4E are sectional views illustratively showing a method of manufacturing a unit is applicable to a method of device structure that manufacturing a semiconductor package device having a fan-out structure, as another embodiment of the present invention.

Referring to FIG. 4A, when disposing a semiconductor chip C10 having a plurality of bumps B10 on a temporary substrate TS10, the semiconductor chip C10 may be disposed on the temporary substrate TS10 such that the bumps B10 face upward. The semiconductor chip C10 may be disposed in a second direction such that the semiconductor chip C10 is located between n the temporary substrate TS10 and the plurality of bumps B10. The second direction may be the opposite direction to the first direction mentioned with reference to FIG. 3B. The plurality of semiconductor chips C10 may be disposed on the temporary substrate TS10, and when a thermal release tape RT10 is used, semiconductor chips C10 may be attached to the thermal release tape RT10.

Referring to FIG. 4B, a non-conductive material layer N14 configured to mold the plurality of semiconductor chips C10 may be formed on the temporary substrate TS10. For example, the non-conductive material layer N14 may be a molding compound or may include the same.

Referring to FIG. 4C, the temporary substrate TS10 (FIG. 4B) may be removed from the plurality of semiconductor chips C10 and the non-conductive material layer N14. At this time, the thermal release tape RT10 (FIG. 4B) may be removed together with the temporary substrate TS10 (FIG. 4B).

Referring to FIG. 4D, one surface of a combined structure in which the plurality of semiconductor chips C10 and the non-conductive material layer N14 are combined with each other may be polished to two-dimensionally expose the plurality of bumps B10. The polishing method may be identical or similar to that described with reference to FIG. 3E.

Referring to FIG. 4E, the combined structure may be divided (cut) into device units to form a plurality of unit device structures D14. In the unit device structure D14, the non-conductive material N14 may be referred to as a non-conductive cover layer N14. The unit device structure D14 may include a semiconductor chip C10 having a plurality of bumps B10 disposed on one surface thereof and a non-conductive cover layer N14. The non-conductive cover layer N14 may be disposed to cover one surface and at least a part of a side surface of the semiconductor chip C10 so as to fill the space between and around the plurality of bumps B10. The non-conductive cover layer N14 may cover at least a part of each of four side surfaces of the semiconductor chip C10. In addition, the non-conductive cover layer N14 may be disposed to expose the plurality of bumps B10. Each of the plurality of bumps B10 may be two-dimensionally exposed from the non-conductive cover layer N14.

In the method of FIGS. 4A, 4B, 4C, 4D, and 4E, polishing of the plurality of bumps B10 may be performed in the step of FIG. 4B. That is, polishing of the plurality of bumps B10 may be performed first, and then the process of removing the temporary substrate TS10 may be performed.

When the plurality of semiconductor chips C10 is disposed on the temporary substrate TS10 and the processes for the plurality of semiconductor chips C10 are simultaneously performed, as in the embodiments of FIGS. 3A, 3B, 3C, 3D, 3E, 3F, 4A, 4B, 4C, 4D, and 4E, the plurality of unit device structures D13 and D14) may be mass-produced, whereby process efficiency may be improved.

According to the embodiments of the present invention, the unit device structures D11, D12, D13, and D14 as shown in FIGS. 1F, 2B, 3F, and 4E may be manufactured. In the unit device structures D11, D12, D13, and D14, each of the bumps B10 two-dimensionally exposed while surrounded by each of the non-conductive cover layers N11, N12, N13, and N14 may function as an electrode pad. The unit device structures D11, D12, D13, and D14 may be easily applied to a fan-out packaging process, such as a chip-first fan-out packaging process.

According to an embodiment, in the unit device structures D11, D12, D13, and D14, each of the non-conductive cover layers N11, N12, N13, and N14 may include a first part disposed on one surface of the semiconductor chip C10 on which the bumps B10 are disposed and a second part extending from the first part so as to cover a part or the entirety of the side surface of the semiconductor chip C10. In some cases, the other surface of the semiconductor chip C10, which is opposite one surface of the semiconductor chip C10, may also be at least partially covered by each of the non-conductive cover layers N11, N12, N13, and N14 or a non-conductive material layer equivalent or similar thereto.

According to an embodiment, in the unit device structures D11, D12, D13, and D14, each of the plurality of bumps B10 may have a polished surface, and the polished surface may be disposed in the same plane as one surface of each of the non-conductive cover layers N11, N12, N13, and N14 and exposed to the outside of each of the non-conductive cover layers N11, N12, N13, and N14.

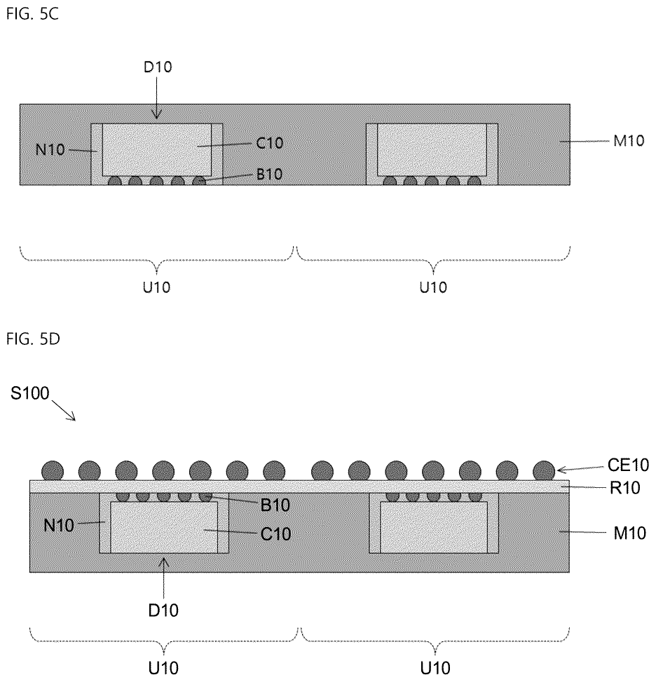

FIGS. 5A, 5B, 5C, 5D, and 5E are sectional views illustratively showing a method of manufacturing a semiconductor package device having a fan-out structure according to an embodiment of the present invention.

Referring to FIG. 5A, a plurality of unit device structures D10 may be disposed on a carrier substrate CS10 so as to be spaced apart from each other in a horizontal direction. At least one of the plurality of unit device structures D10 may be disposed in each of a plurality of two-dimensionally arranged unit package regions U10. Each of the unit device structures D10 may y have the configuration described with reference to FIGS. 1F, 2B, 3F, and 4E. That is, the unit device structure D10 may correspond to each of the unit device structures D11, D12, D13, and D14 of FIGS. 1F, 2B, 3F, and 4E. The unit device structure D10 may include a semiconductor chip C10 having a plurality of bumps B10 disposed on one surface thereof and a non-conductive cover layer N10 disposed to cover one surface and at least a part of a side surface of the semiconductor chip C10 so as to fill the space between and around the plurality of bumps B10, the non-conductive cover layer N10 being configured to expose the plurality of bumps B10.

An adhesive layer AL10 may be provided on the carrier substrate CS10, and the plurality of unit device structures D10 may be attached to the adhesive layer AL10. In other words, the plurality of unit device structures D10 may be attached to the carrier substrate CS10 in the state in which the adhesive layer AL10 is interposed therebetween. The adhesive layer AL10 may be an adhesive film. The carrier substrate CS10 may be a wafer or a panel. The plurality of unit device structures D10 may be attached to the carrier substrate CS10, for example, in a face-down manner. In other words, the unit device structures D10 may be attached to the carrier substrate CS10 such that the plurality of bumps B10 faces downward.

Referring to FIG. 5B, a molding material layer M10 configured to cover the plurality of unit device structures D10 may be formed on the carrier substrate CS10. The molding material layer M10 may include a polymer material. For example, the molding material layer M10 may be a molding compound or may include the same.

Referring to FIG. 5C, the carrier substrate CS10 (FIG. 5B) may be removed from the plurality of unit device structures D10 and the molding material layer M10. In other words, the carrier substrate CS10 (FIG. 5B) may be removed from a substrate structure including the molding material layer M10 and the plurality of unit device structures D10. At this time, the adhesive layer AL10 (FIG. 5B) may also be removed.

Referring to FIG. 5D, a redistribution layer structure R10 may be formed on the substrate structure including the molding material layer M10 and the plurality of unit device structures D10. The redistribution layer structure R10 may be electrically connected to the plurality of bumps B10. The redistribution layer structure R10 may be in contact with the plurality of bumps B10. The redistribution layer structure R10 may serve to redistribute the plurality of bumps B10 of the unit device structure D10. The redistribution layer structure R10 may be formed through processes such as forming an insulating layer having a via hole (opening), forming a seed layer, forming a mask pattern, electroplating a wiring layer, and removing the mask pattern. Although the redistribution layer structure R10 is simply shown in this figure, the redistribution layer structure R10 may include a structure in which an insulating layer (e.g., an organic insulating layer) and a wiring member layer (wiring element layer) are alternately stacked at least once. The insulating layer may have a plurality of via holes (openings) formed therein, and conductive via elements may be provided in the via holes. The conductive via element may serve as a vertical wire.

In addition, a plurality of electrical connection elements CE10 may be further formed on the redistribution layer structure R10. For each of the plurality of unit package regions U10, the plurality of electrical connection elements CE10 may be formed on one surface of the redistribution layer structure R10. As a non-limiting example, each of the plurality of electrical connection elements CE10 may include a solder ball or a bump. The plurality of electrical connection elements CE10 may be connected a predetermined circuit board (e.g., a motherboard).

The plurality of unit device structures D10, the molding material layer M10, the redistribution layer structure R10, and the plurality of electrical connection elements CE10 may be said to constitute a packaging structure S100. The packaging structure S100 may include a plurality of package device regions.

Referring to FIG. 5E, the packaging structure S100 (FIG. 5D) may be divided (cut) into package device units corresponding to the plurality of unit package regions U10, respectively. This may be performed using a general dividing (cutting) method. As a result, individualized semiconductor package devices S10a and S10b may be obtained. In the semiconductor package devices S10a and S10b, the molding material layer M10 may be referred to as a “molding layer”, and the redistribution layer structure R10 may be referred to as a “redistribution layer member”.

Hereinafter, a semiconductor package device having a fan-out structure according to an embodiment of the present invention will be described with reference to the semiconductor package device S10a of FIG. 5E.

The semiconductor package device S10a according to the embodiment may have a fan-out structure. In this regard, the area occupied by a plurality of electrical connection elements CE10, i.e., the area of the space in which the plurality of electrical connection elements CE10 is disposed, may be greater than the size of a unit device structure D10. The unit device structure D10 may include a semiconductor chip C10 having a plurality of bumps B10 disposed on one surface thereof and a non-conductive cover layer N10 disposed to cover one surface and at least a part of a side surface of the semiconductor chip C10 so as to fill the space between and around the plurality of bumps B10, the non-conductive cover layer N10 being configured to expose the plurality of bumps B10.

The semiconductor package device S10a may include a molding layer M10 and a redistribution layer member R10. The molding layer M10 may form a single substrate layer together with the unit device structure D10 while filling the space around the unit device structure D10, and may expose one surface of the unit device structure D10 such that the plurality of bumps B10 is exposed. The redistribution layer member R10 may be disposed on one surface of the substrate layer including the unit device structure D10 and the molding layer M10 so as to be electrically connected to the plurality of bumps B10. In addition, the semiconductor package device S10a may include a plurality of electrical connection elements CE10 disposed on one surface of the redistribution layer member R10 so as to be electrically connected to the semiconductor chip C10 via the redistribution layer member R10 on the side opposite the side on which the substrate layer is disposed.

All of the details described with reference to FIGS. 1A, 1B, 1C, 1D, 1E, 1F, 2A, 2B, 3A, 3B, 3C, 3D, 3E, 3F, 4A, 4B, 4C, 4D, and 4E may be applied to the specific configuration and features of the unit device structure D10, a redundant description of which will therefore be omitted.

The semiconductor package device according to the embodiment of the present invention may be manufactured using a fan-out packaging method. For example, the semiconductor package device may be manufactured using a fan-out panel level packaging (FOPLP) method or a fan-out wafer level packaging (FOWLP) method. As a specific example, a plurality of unit device structures may be attached to a predetermined carrier substrate, a molding layer configured to fix the plurality of unit device structures may be formed on the carrier substrate, a redistribution layer member electrically connected to the plurality of unit device structures may be formed, and a plurality of electrical connection elements may be formed on the redistribution layer member. The plurality of unit device structures may be attached to the carrier substrate, for example, in a face-down manner. In addition, a chip-first method may be used when manufacturing the semiconductor package device.

According to the embodiment of the present invention described above, a chip or package (package chip) having bumps may be applied to chip-first fan-out packaging to manufacture a semiconductor package device. In this regard, various advantages of chip-first fan-out packaging may be easily obtained.

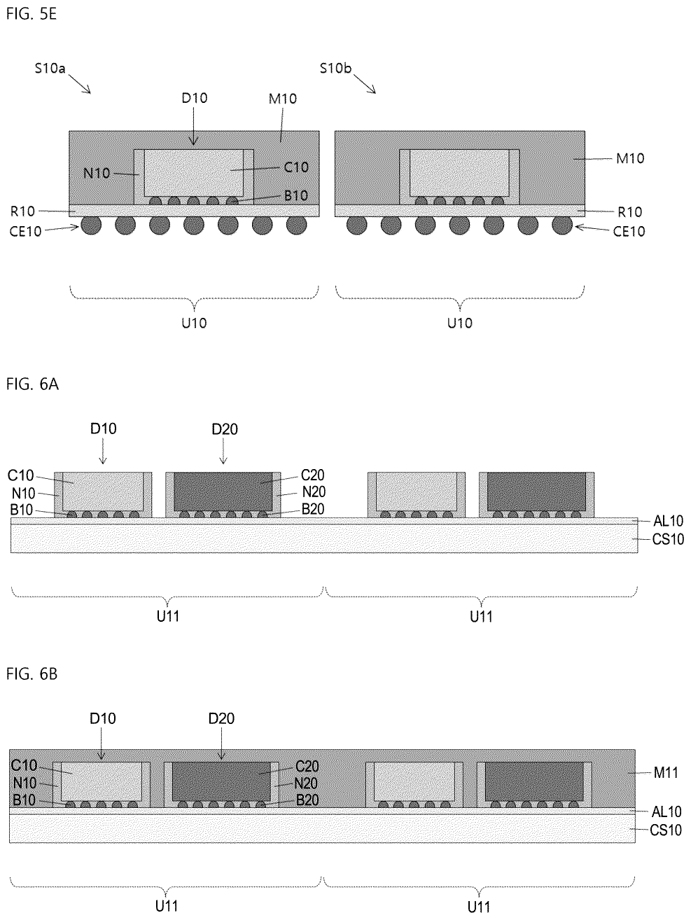

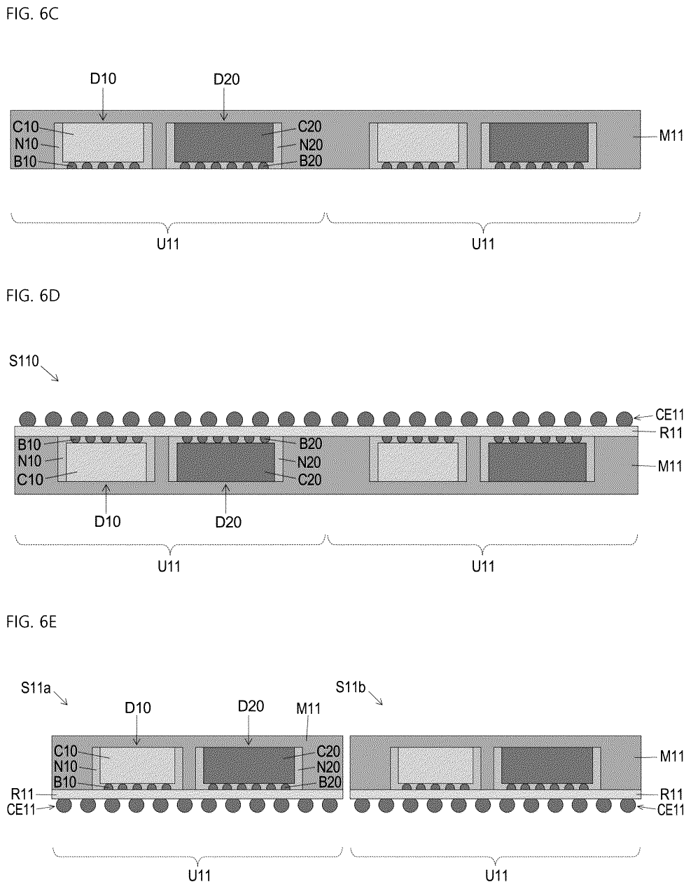

The semiconductor package device according to the embodiment of the present invention may have a single-chip package structure or a multi-chip package structure. Each of the semiconductor package devices S10a and S10b of FIG. 5E may have a single-chip package structure. Hereinafter, a method of manufacturing a semiconductor package device having a multi-chip package structure will be described with reference to FIGS. 6A, 6B, 6C, 6D, and 6E.

FIGS. 6A, 6B, 6C, 6D, and 6E are sectional views illustratively showing a method of manufacturing a semiconductor package device having a fan-out structure according to another embodiment of the present invention.

Referring to FIG. 6A, a plurality of unit device structures D10 and D20 may be disposed on a carrier substrate CS10 so as to be spaced apart from each other in the horizontal direction. The plurality of unit device structures D10 and D20 may include a plurality of first unit device structures D10 and a plurality of second unit device structures D20. At least two of the plurality of unit device structures D10 and D20 may include different types of semiconductor chips. The first unit device structure D10 and the second unit device structure D20 may include different types of semiconductor chips. The plurality of unit device structures D10 and D20 may be disposed in a plurality of two-dimensionally arranged unit package regions U11. At least one first unit device structure D10 and at least one second unit device structure D20 may be disposed in each of the plurality of unit package regions U11.

At least one of the first and second unit device structures D10 and D20 may have a configuration corresponding to that described with reference to FIGS. 1F, 2B, 3F, and 4E. That is, the configuration of at least one of the first and second unit device structures D10 and D20 may correspond to that of each of the unit device structures D11, D12, D13, and D14 of FIGS. 1F, 2B, 3F, and 4E.

The first unit device structure D10 may include semiconductor chip C10 having a plurality of bumps B10 disposed on one surface thereof and a non-conductive cover layer N10 disposed to cover one surface and at least a part of a side surface of the semiconductor chip C10 so as to fill the space between and around the plurality of bumps B10, the non-conductive cover layer N10 being configured to expose the plurality of bumps B10. The bumps B10 may be referred to as first bumps, the semiconductor chip C10 may be referred to as a first semiconductor chip, and the non-conductive cover layer N10 may be referred to as a first non-conductive cover layer.

The second unit device structure D20 may include a semiconductor chip C20 having a plurality of bumps B20 disposed on one surface thereof and a non-conductive cover layer N20 disposed to cover one surface and at least a part of a side surface of the semiconductor chip C20 so as to fill the space between and around the plurality of bumps B20, the non-conductive cover layer N20 being configured to expose the plurality of bumps B20. The bumps B20 may be referred to as second bumps, the semiconductor chip C20 may be referred to as a second semiconductor chip, and the non-conductive cover layer N20 may be referred to as a second non-conductive cover layer.

An adhesive layer AL10 may be provided on the carrier substrate CS10, and the plurality of unit device structures D10 and D20 may be attached to the adhesive layer AL10. In other words, the plurality of unit device structures D10 and D20 may be attached to the carrier substrate CS10, for example, in a face-down manner. The adhesive layer AL10 may be an adhesive film.

Referring to FIG. 6B, a molding material layer M11 configured to cover the plurality of unit device structures D10 and D20 may be formed on the carrier substrate CS10.

Referring to FIG. 6C, the carrier substrate CS10 (FIG. 6B) may be removed from the plurality of unit device structures D10 and D20 and the molding material layer M11. In other words, the carrier substrate CS10 (FIG. 6B) may be removed from a substrate structure including the molding material layer M11 and the plurality of unit device structures D10 and D20. At this time, the adhesive layer AL10 (FIG. 6B) may also be removed.

Referring to FIG. 6D, a redistribution layer structure R11 may be formed on the substrate structure including the molding material layer M11 and the plurality of unit device structures D10 and D20. The redistribution layer structure R11 may be electrically connected to the plurality of bumps B10 and B20. The redistribution layer structure R11 may be in contact with the plurality of bumps B10 and B20. The redistribution layer structure R11 may serve to redistribute the arrangement of the bumps B10 and B20 of the unit device structures D10 and D20. In addition, a plurality of electrical connection elements CE11 may be further formed on the redistribution layer structure R11. For each of the plurality of unit package regions U11, the plurality of electrical connection elements CE11 may be formed on one surface of the redistribution layer structure R11.

The plurality of unit device structures D10 and D20, the molding material layer M11, the redistribution layer structure R11, and the plurality of electrical connection elements CE11 may be said to constitute a packaging structure S110. The packaging structure S110 may include a plurality of package device regions.

Referring to FIG. 6E, the packaging structure S110 (FIG. 6D) may be divided (cut) into package device units corresponding respectively to the plurality of unit package regions U11, whereby individualized semiconductor package devices S11a and S11b may be obtained. In the semiconductor package devices S11a and S11b, the molding material layer M11 may be referred to as a “molding layer”, and the redistribution layer structure R11 may be referred to as a “redistribution layer member”.

A semiconductor package device S11a according to an embodiment may include at least two unit device structures D10 and D20. In this case, the semiconductor package device S11a may be said to have a multi-chip package structure. Each of the at least two unit device structures D10 and D20 may include heterogeneous chips. For example, each of the at least two unit device structures D10 and D20 may include a memory chip and a logic chip, and may further include other types of chips. The at least two unit device structures D10 and D20 may be disposed on the redistribution layer member R11 so as to be spaced apart from each other in the horizontal direction. According to the embodiment of the present invention, the heterogeneous chips may be easily connected to each other. Three or more unit device structures may be applied to a single semiconductor package device S11a.

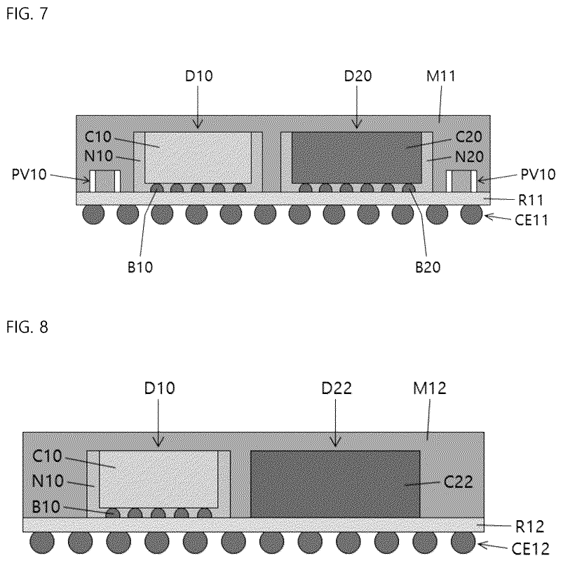

FIG. 7 is a sectional view illustratively showing a semiconductor package device having a fan-out structure according to another embodiment of the present invention.

Referring to FIG. 7, the semiconductor package device according to this embodiment may further include at least one passive device member PV10 disposed in a molding layer M11 around unit device structures D10 and D20, the at least one passive device member PV10 being electrically connected to a redistribution layer member R11. The at least one passive device member PV10 may be in contact with the redistribution layer member R11, and may be connected to at least one of the plurality of unit device structures D10 and D20 or to at least one of a plurality of electrical connection elements CE11 via the redistribution layer member R11. As a non-limiting example, the passive element member PV10 may be a capacitor or may include a capacitor.

The semiconductor package device of FIG. 7 may be identical or similar in configuration to the semiconductor package device Sla of FIG. 6E except for the passive element member PV10. In the step of FIG. 6A, the at least one passive element member PV10 may be disposed on the carrier substrate CS10 together with the plurality of unit device structures D10 and D20, whereby a semiconductor package device as shown in FIG. 7 may be manufactured.

When the semiconductor package device according to the embodiment of the present invention has a multi-chip package structure, at least one of the plurality of unit device structures included in the semiconductor package device may have a bump-less chip structure or a bump-less package chip structure. An example thereof is shown in FIG. 8.

FIG. 8 is a sectional view illustratively showing a semiconductor package device having a fan-out structure according to another embodiment of the present invention.

Referring to FIG. 8, the semiconductor package device according to this embodiment may include at least two unit device structures D10 and D22. The at least two unit device structures D10 and D22 may include a first unit device structure D10 and a second unit device structure D22. The first unit device structure D10 may have a configuration corresponding to that described with reference to FIGS. 1F, 2B, 3F, and 4E. The first unit device structure D10 may include a semiconductor chip C10 having a plurality of bumps B10 disposed on one surface thereof and a non-conductive cover layer N10 disposed to cover one surface and at least a part of a side surface of the semiconductor chip C10 so as to fill the space between and around the plurality of bumps B10, the non-conductive cover layer N10 being configured to expose the plurality of bumps B10. Meanwhile, the second unit device structure D22 may include a semiconductor chip C22, and the semiconductor chip C22 may have a bump-less chip structure or a bump-less package chip structure.

The semiconductor package device may include a molding layer M12, a redistribution layer member R12, and a plurality of electrical connection elements CE12. The molding layer M12, the redistribution layer member R12, and the plurality of electrical connection elements CE12 may correspond to the molding layer M11, the redistribution layer member R11, and the plurality of electrical connection elements CE11 of FIG. 6E, respectively. The semiconductor chip C22 may have a plurality of electrode pads (not shown) provided on a surface thereof, and the plurality of electrode pads may be disposed so as to face the redistribution layer member R12 and to be electrically connected to/in contact with the redistribution layer member R12. In the step of FIG. 6A, the first unit device structure D10 and the second unit device structure D22 may be disposed on the carrier substrate CS10 and the method of FIGS. 6B, 6C, 6D, and 6E may be used, whereby a semiconductor package device as shown in FIG. 8 may be manufactured.

According to embodiments of the present invention, it is possible to implement technology and methods capable of applying a chip/package or product having bumps to fan-out packaging. In addition, according to the embodiments of the present invention, it is possible to implement a method of manufacturing a semiconductor package device by applying a chip or package (package chip) having bumps to, for example, chip-first fan-out packaging and a semiconductor package device manufactured thereby.

According to the embodiments of the present invention, it is possible to utilize the advantages of chip-first fan-out packaging even when a high bandwidth memory (HBM) or other products are provided in the form of a chip or package having bumps. Therefore, even for a chip/package/product having bumps, it is possible to overcome the limitations and problems of existing packages using an interposer.

However, the effects of the present invention are not limited to the above effects, and may be variously expanded without departing from the technical ideas and scope of the present invention.

What is claimed is:

1. A method of manufacturing a semiconductor package device having a fan-out structure, the method comprising:
providing a unit device structure comprising a semiconductor chip having a plurality of bumps disposed on one surface thereof and a non-conductive cover layer disposed to cover the one surface and at least a part of a side surface of the semiconductor chip so as to fill a space between and around the plurality of bumps, the non-conductive cover layer being configured to expose the plurality of bumps; and
manufacturing a semiconductor package device having a fan-out structure using the unit device structure, the semiconductor package device comprising the unit device structure, a molding layer configured to form a single substrate layer together with the unit device structure while filling a space around the unit device structure, the molding layer being configured to expose one surface of the unit device structure such that the plurality of bumps is exposed, a redistribution layer member disposed on one surface of the substrate layer comprising the unit device structure and the molding layer so as to be electrically connected to the plurality of bumps, and a plurality of electrical connection elements disposed on one surface of the redistribution layer member so as electrically connected to the semiconductor chip via the redistribution layer member on a side opposite a side on which the substrate layer is disposed.

2. The method according to claim 1, wherein the step of providing the unit device structure comprises:
providing a molding tool comprising a molding unit having an accommodation region;
filling at least a part of the accommodation region with a non-conductive material;
disposing the semiconductor chip having a plurality of bump elements in the accommodation region filled with the non-conductive material in the at least a part thereof;
separating a combined body in which the semiconductor chip and the non-conductive material are combined with each other from the molding unit; and
polishing one surface of the combined body to two-dimensionally expose the plurality of bump elements, and
after the polishing, the combined body corresponds to the unit device structure, the plurality of bump elements correspond to the plurality of bumps, and the non-conductive material corresponds to the non-conductive cover layer.

3. The method according to claim 2, wherein the non-conductive material in the combined body is disposed so as to cover a part or an entirety of the side surface of the semiconductor chip.

4. The method according to claim 1, wherein the step of providing the unit device structure comprises:
providing a temporary substrate;
disposing the semiconductor chip having the plurality of bump elements on the temporary substrate, the semiconductor chip being provided in plural;
forming a non-conductive material layer configured to mold the plurality of semiconductor chips on the temporary substrate;
polishing one surface of a combined structure in which the plurality of semiconductor chips and the non-conductive material layer are combined with each other to two-dimensionally expose the plurality of bump elements; and
dividing the combined structure into device units to form the unit device structure in plural in a state in which the temporary substrate is excluded, and
after the polishing or the dividing, the plurality of bump elements corresponds to the plurality of bumps, and the non-conductive material layer corresponds to the non-conductive cover layer.

5. The method according to claim 4, wherein
in the step of disposing the plurality of semiconductor chips on the temporary substrate,
each semiconductor chip is disposed in a first direction such that the plurality of bump elements is located between the temporary substrate and the semiconductor chip, or
each semiconductor chip is disposed in a second direction opposite the first direction such that the semiconductor chip is located between the temporary substrate and the plurality of bump elements.

6. The method according to claim 1, wherein the non-conductive cover layer comprises:
a first part disposed on the one surface of the semiconductor chip; and
a second part extending from the first part so as to cover a part or an entirety of the side surface of the semiconductor chip.

7. The method according to claim 1, wherein each of the plurality of bumps has a polished surface, and the polished surface is disposed in the same plane as one surface of the non-conductive cover layer and exposed to an outside of the non-conductive cover layer.

8. The method according to claim 1, wherein
the semiconductor package device comprises a plurality of unit device structures, at least one of which corresponds to the unit device structure, the plurality of unit device structures being disposed spaced apart from each other in a horizontal direction, and
the molding layer is disposed so as to fill a space between and around the plurality of unit device structures.

9. The method according to claim 8, wherein at least two of the plurality of unit device structures comprise different types of semiconductor chips.

10. The method according to claim 1, wherein the step of manufacturing the semiconductor package device comprises:
disposing a plurality of unit device structures on a carrier substrate so as to be spaced apart from each other in a horizontal direction, at least one of the plurality of unit device structures being disposed in each of a plurality of two-dimensionally arranged unit package regions;
forming a molding material layer configured to cover the plurality of unit device structures on the carrier substrate;
removing the carrier substrate from a substrate structure comprising the molding material layer and the plurality of unit device structures;
forming a redistribution layer structure electrically connected to the plurality of bumps on one surface of the substrate structure;
forming the plurality of electrical connection elements on one surface of the redistribution layer structure in each of the plurality of unit package regions; and
dividing a packaging structure comprising the plurality of unit device structures, the molding material layer, the redistribution layer structure, and the plurality of electrical connection elements into package device units corresponding to the plurality of unit package regions, respectively.

11. The method according to claim 1, wherein the semiconductor package device has a single-chip package structure or a multi-chip package structure.

12. A semiconductor package device having a fan-out structure, the semiconductor package device comprising:
a unit device structure comprising a semiconductor chip having a plurality of bumps disposed on one surface thereof and a non-conductive cover layer disposed to cover the one surface and at least a part of a side surface of the semiconductor chip so as to fill a space between and around the plurality of bumps, the non-conductive cover layer being configured to expose the plurality of bumps;
a molding layer configured to form a single substrate layer together with the unit device structure while filling a space around the unit device structure, the molding layer being configured to expose one surface of the unit device structure such that the plurality of bumps is exposed;
a redistribution layer member disposed on one surface of the substrate layer comprising the unit device structure and the molding layer so as to be electrically connected to the plurality of bumps; and
a plurality of electrical connection elements disposed on one surface of the redistribution layer member so as to be electrically connected to the semiconductor chip via the redistribution layer member on a side opposite a side on which the substrate layer is disposed.

13. The semiconductor package device according to claim 12, wherein the non-conductive cover layer comprises:
a first part disposed on the one surface of the semiconductor chip; and
a second part extending from the first part so as to cover a part or an entirety of the side surface of the semiconductor chip.

14. The semiconductor package device according to claim 12, wherein each of the plurality of bumps has a polished surface, and the polished surface is disposed in the same plane as one surface of the non-conductive cover layer and exposed to an outside of the non-conductive cover layer.

15. The semiconductor package device according to claim 12, wherein
a plurality of unit device structures, at least one of which corresponds to the unit device structure, is disposed spaced apart from each other in a horizontal direction, and
the molding layer is disposed so as to fill a space between and around the plurality of unit device structures.

16. The semiconductor package device according to claim 15, wherein at least two of the plurality of unit device structures comprise different types of semiconductor chips.

17. The semiconductor package device according to claim 12, wherein the semiconductor package device has a single-chip package structure or a multi-chip package structure.
